(19) United States
(12) Patent Application Publication
(10) Pub. No.: US 2025/0235954 A1
(43) Pub. Date: Jul. 24, 2025

(54) LASER LIFT-OFF APPARATUS AND LASER LIFT-OFF METHOD

(71) Applicant: Samsung Display Co., LTD., Yongin-si (KR)

(72) Inventors: Young Su CHAE, Yongin-si (KR); Akifumi SANGU, Yongin-si (KR); Cheol Ho PARK, Yongin-si (KR)

(21) Appl. No.: 18/773,941

(22) Filed: Jul. 16, 2024

(30) Foreign Application Priority Data
Jan. 22, 2024 (KR) 10-2024-0009582

(51) Int. Cl. B23K 26/082; B23K 26/06; B23K 26/10

(52) U.S. Cl. CPC B23K 26/082; B23K 26/0604; B23K 26/0643

(57) ABSTRACT

A laser lift-off apparatus includes a laser beam generating unit which generates a laser beam, an optical unit which receives the laser beam and generates output light based on the laser beam; and a stage unit including a stage. The optical unit includes a driving mirror unit which changes an advancing path of at least a portion of the laser beam, where a direction or a position of the driving mirror unit is changeable.

This application claims priority to Korean patent application No. 10-2024-0009582, filed on Jan. 22, 2024, and all the benefits accruing therefrom under 35 U.S.C. § 119, the content of which in its entirety is herein incorporated by reference.

### BACKGROUND

### 1. Field

The disclosure generally relates to a laser lift-off apparatus and a laser lift-off method.

### 2. Related Art

A display device may be manufactured as a flexible device, using a flexible substrate having high flexibility.

However, since the flexible substrate has high flexibility, it is desired for the flexible substrate to be supported during a manufacturing process of the display device. Therefore, after the flexible substrate is formed on a carrier substrate formed of a material such as glass, a process of manufacturing a flat panel display device may be performed, and then the carrier substrate may be removed.

The carrier substrate may be removed by various methods, and studies on a laser lift-off method using laser among the various methods have been actively conducted.

### SUMMARY

Embodiments provide a laser lift-off apparatus and a laser lift-off method, which can prevent components of a display device from being damaged during a laser lift-off process.

In accordance with an embodiment of the disclosure, a laser lift-off apparatus includes: a laser beam generating unit which generates a laser beam; an optical unit which receives the laser beam to generate output light;

and a stage unit including a stage, where the optical unit includes a driving mirror unit which changes an advancing path of at least a portion of the laser beam, where a direction or a position of the driving mirror unit is changeable.

In an embodiment, the optical unit may further include: a combiner which combines the laser beam and provides a combined laser beam to a light former; and the light former including the driving mirror unit, where the light former may generate the output light based the combined laser beam.

In an embodiment, the driving mirror unit may include a first driving mirror unit and a second driving mirror unit, which are spaced apart from each other in a first direction. In such an embodiment, each of the first driving mirror unit and the second driving mirror unit may include a reflective surface by which the laser beam is reflected. In such an embodiment, a direction of the reflective surface or a position of the reflective surface may be changeable. In an embodiment, the first driving mirror unit may include: a first reflective member including the reflective surface; and a first rotating shaft coupled to a surface adjacent to the reflective surface of the first reflective member, where the first rotating shaft extends in a second direction intersecting the first direction. In such an embodiment, a direction of the reflective surface of the first driving mirror unit may be changeable.

In an embodiment, the reflective surface of the first driving mirror unit may form a first angle with an imaginary surface perpendicular to a ground surface. In such an embodiment, the first angle may be about zero (0) degree or greater and less than about 90 degrees.

In an embodiment, as a magnitude of the first angle increases, a partial area in which an energy density of the output light is the highest may move in the first direction.

In an embodiment, the first driving mirror unit may include: a first reflective member including the reflective surface; and a first rotating shaft coupled to an opposite surface opposite to the reflective surface of the first reflective member, where the first rotating shaft extends in a second direction intersecting the first direction. In such an embodiment, a direction of the reflective surface of the first driving mirror unit may be changeable. In an embodiment, a position of the reflective surface of the first driving

mirror unit may be changeable through a movement of the first driving mirror unit in the first direction or an opposite direction of the first direction.

In an embodiment, a position of the reflective surface of the first driving mirror unit may be changeable through a movement of the first driving mirror unit in a third direction intersecting the first direction or an opposite direction of the third direction.

In an embodiment, the laser beam may have a wavelength in a range of about 300 nanometers (nm) to about 410 nm.

In accordance with another embodiment of the disclosure, a laser lift-off method includes: disposing a carrier substrate on a stage; sealing the stage; allowing output light generated based on a laser beam to be incident onto a back surface of the carrier substrate; and allowing a panel substrate disposed on a front surface of the carrier substrate to be lifted off from the carrier substrate, where the allowing the output light to be incident onto the back surface of the carrier substrate includes: generating the laser beam; allowing at least a portion of the laser beam to pass through a driving mirror unit such that an advancing path of the at least a portion of the laser beam is changed; and generating the output light.

In an embodiment, the allowing the output light to be incident onto the back surface of the carrier substrate may further include combining the laser beam.

In an embodiment, the driving mirror unit may include a first driving mirror unit and a second driving mirror unit, which are spaced apart from each other in a first direction. In such an embodiment, each of the first driving mirror unit and the second driving mirror unit may include a reflective surface by which the laser beam is reflected. In such an embodiment, a direction of the reflective surface or a position of the reflective surface may be changeable.

In an embodiment, the first driving mirror unit may include: a first reflective member including the reflective surface; and a first rotating shaft coupled to a surface adjacent to the reflective surface of the first reflective member, where the first rotating shaft extends in a second direction intersecting the first direction. In such an embodiment, a direction of the reflective surface of the first driving mirror unit may be changeable.

In an embodiment, The reflective surface of the first driving mirror unit may form a first angle with an imaginary surface perpendicular to a ground surface. In such an embodiment, the first angle may be about zero (0) degree or greater and less than about 90 degrees.

In an embodiment, an energy density of a partial area of the output light may be the highest. In such an embodiment, as a magnitude of the first angle increases, the partial area of the output light may move in the first direction.

In an embodiment, the first driving mirror unit may include: a first reflective member including the reflective surface; and a first rotating shaft coupled to an opposite surface opposite to the reflective surface of the first reflective member, the first rotating shaft extending in a second direction intersecting the first direction. In such an embodiment, a direction of the reflective surface of the first driving mirror unit may be changeable.

In an embodiment, a position of the reflective surface of the first driving mirror unit may be changeable through a movement of the first driving mirror unit in the first direction or an opposite direction of the first direction.

In an embodiment, a position of the reflective surface of the first driving mirror unit may be changeable through a movement of the first driving mirror unit in a third direction intersecting the first direction or an opposite direction of the third direction.

In an embodiment, the laser beam may have a wavelength in a range of about 300 nm to about 410 nm.

### BRIEF DESCRIPTION OF THE DRAWINGS

The above and other features of the invention will become more apparent by describing in further detail embodiments thereof with reference to the accompanying drawings, in which:

FIG. 1 is a schematic view illustrating a laser lift-off apparatus in accordance with embodiments of the disclosure;

FIG. 2 is a schematic view illustrating a light former in accordance with embodiments of the disclosure;

FIG. 3 is an enlarged view of the encircled portion X of FIG. 2 in accordance with an embodiment of the disclosure;

FIG. 4 is a schematic perspective view of a first driving mirror unit shown in FIG. 3;

FIGS. 5 and 6 are graphs illustrating energy density of output light for each area according to the magnitude of a first angle shown in FIG. 3;

FIG. 7 is an enlarged view of the encircled portion X of FIG. 2 in accordance with another embodiment of the disclosure;

FIG. 8 is a schematic perspective view of a first driving mirror unit shown in FIG. 7;

FIG. 9 is an enlarged view of the encircled portion X of FIG. 2 in accordance with another embodiment of the disclosure;

FIG. 10 is an enlarged view of the encircled portion X of FIG. 2 in accordance with another embodiment of the disclosure;

FIG. 11 is a schematic view illustrating a stage unit in accordance with embodiments of the disclosure;

FIG. 12 is a schematic view illustrating a carrier substrate and a display device, which may be disposed in the stage unit shown in FIG. 11;

FIG. 13 is a schematic view illustrating an operation of the laser lift-off apparatus in accordance with embodiments of the disclosure;

FIG. 14 is a schematic plan view of area S1 shown in FIG. 12;

FIG. 15 is a schematic plan view of area S2 shown in FIG. 14;

FIG. 16 is a schematic view illustrating laser energy density applied to a carrier substrate and a panel substrate when a laser lift-off process is performed in accordance with embodiments of the disclosure;

FIG. 17 is a schematic view illustrating that the carrier substrate and the panel substrate are lifted off from each other, using the laser lift-off apparatus in accordance with embodiments of the disclosure; and

FIGS. 18 and 19 are flowcharts illustrating a laser lift-off method in accordance with embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

In the entire specification, when an element is referred to as being “connected” or “coupled” to another element, it can be directly connected or coupled to the another element or be indirectly connected or coupled to the another element with one or more intervening elements interposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from X, Y, and Z” can be construed as X only, Y only, Z only, or any combination of two or more items X, Y, and Z (e.g., XYZ, XYY, YZ, ZZ).

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

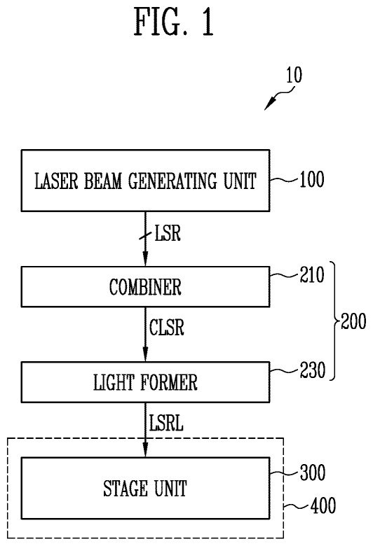

FIG. 1 is a schematic view illustrating a laser lift-off apparatus in accordance with embodiments of the disclosure.

Referring to FIG. 1, an embodiment of the laser lift-off apparatus 10 may include a laser beam generating unit 100, an optical unit 200, a stage unit 300, and a chamber 400.

The laser lift-off apparatus 10 may be configured to remove a carrier substrate, using laser.

The laser beam generating unit 100 may generate a laser beam LSR.

In an embodiment, for example, the laser beam generating unit 100 may generate the laser beam LSR, using excimer laser. However, embodiments of the disclosure are not limited thereto. In some embodiments, the laser beam generating unit 100 may generate the laser beam LSR, using solid state laser.

In some embodiments, the laser beam generating unit 100 may include a plurality of light sources.

Each of the plurality of light sources may generate the laser beam LSR, using laser. The laser beam LSR may be generated in a Gaussian form. The laser beam LSR may have a wavelength in a range of about 300 nanometers (nm) to about 410 nm.

The optical unit 200 may receive the laser beam LSR transferred from the laser beam generating unit 100. The optical unit 200 may generate output light LSRL, based on the laser beam LSR. In an embodiment, for example, the output light LSRL may have a line shape (or rectangle shape) having a major axis length and a minor axis length. The major axis length may mean a line length, and the minor axis length may mean a line width. However, embodiments of the disclosure are not limited thereto. In an embodiment, for example, the major axis length may mean the line width, and the minor axis length may mean the line length. The shape of the output light LSRL may be diversely modified.

The optical unit 200 may supply the output light LSRL to the stage unit 300.

The optical unit 200 may include a combiner 210 and a light former 230.

The combiner 210 may include at least one selected from a phase retarder, a lens, and a mirror.

The combiner 210 may generate a combined laser beam CLSR. The combiner 210 may supply the combined laser beam CLSR to the light former 230.

The light former 230 may generate the output light LSRL, based on the combined laser beam CLSR. The light former 230 may supply the output light LSRL to the stage unit 300.

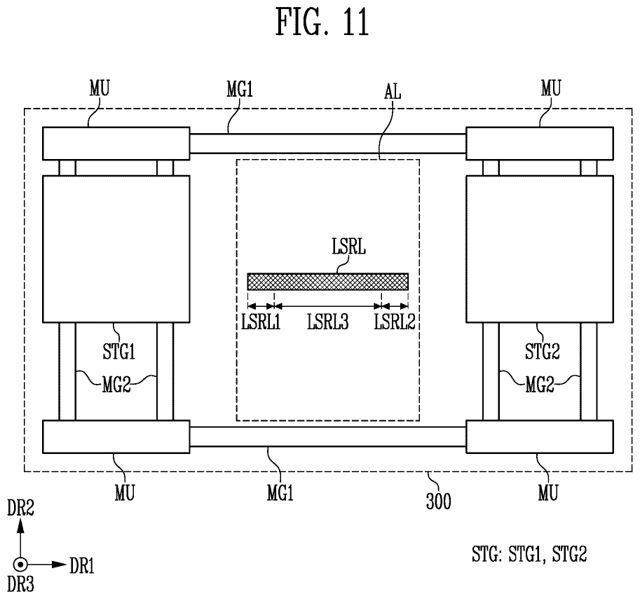

The stage unit 300 may include at least one stage on which a target object is disposed for performing a laser lift-off process. This will be described later in greater detail with reference to FIG. 11.

The chamber 400 may provide an environment for performing processes. In an embodiment, for example, the chamber 400 may provide a space in which the stage unit 300 can be disposed, and provide a vacuum environment for processes and an environment for external air blocking or the like. The chamber 400 may separate the at least one stage included in the stage unit 300 from an outside.

In an embodiment, for example, the chamber 400 may seal the at least one stage from the outside to prevent an ozone gas generated due to high irradiance of ultraviolet light radiation from being discharged to the outside.

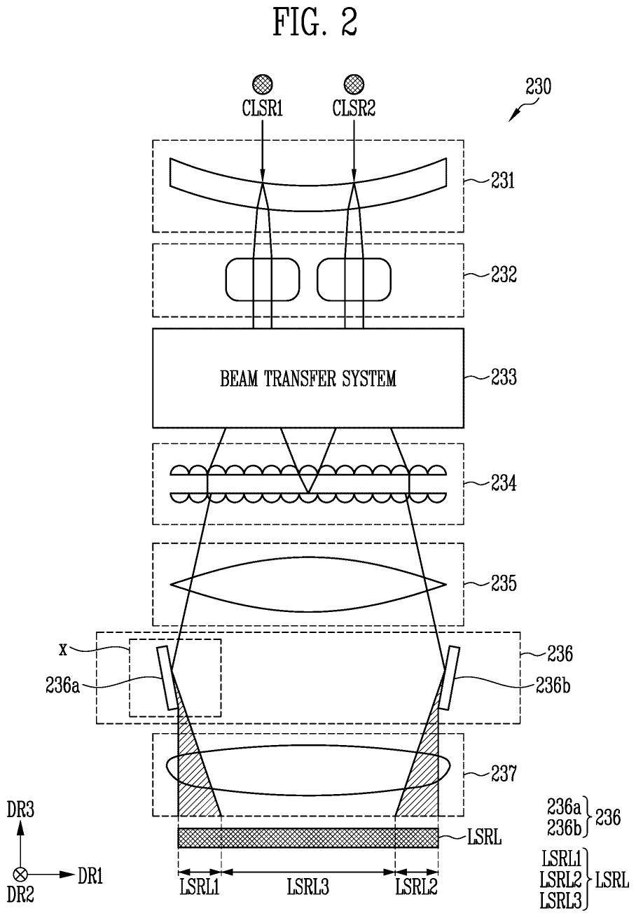

FIG. 2 is a schematic view illustrating a light former in accordance with embodiments of the disclosure.

Referring to FIG. 2, an embodiment of the light former 230 may include a telescope lens set 231, a cylindrical lens 232, a beam transfer system 233, a homogenizer 234, a first convex lens 235, a driving mirror unit 236, and a second convex lens 237.

Although an embodiment in which the telescope lens set 231, the cylindrical lens 232, the beam transfer system 233, and the homogenizer 234 are implemented with a lens is illustrated in FIG. 2, embodiments of the disclosure are not limited thereto. In some embodiments, the telescope lens set 231, the cylindrical lens 232, the beam transfer system 233, and the homogenizer 234 may be implemented using at least one selected from a lens and a mirror.

The telescope lens set 231 may diffuse a combined laser beam CLSR including a first combined laser beam CLSR1 and a second combined laser beam CLSR2, supplied thereto. The combined laser beam CLSR may have a circular shape. However, embodiments of the disclosure are not limited thereto.

The combined laser beam CLSR may have various shapes.

In an embodiment, as shown in FIG. 2, the telescope lens set 231 may include a single lens. However, embodiments of the disclosure are not limited thereto. In some embodiments, the telescope lens set 231 may include a plurality of lenses.

The cylindrical lens 232 may control light input from the telescope lens set 231. In an embodiment, for example, the cylindrical lens 232 may control the light width of the input light to be further narrowed.

The beam transfer system 233 may control light input from the cylindrical lens 232. In an embodiment, for example, the beam transfer system 233 may rotate the input light, thereby rotating a light width direction.

In some embodiments, the beam transfer system 233 and the homogenizer 234 may include a saw tooth lens or a light guide including or made of mirrors. In addition, the homogenizer 234 may include a fly's eye lens.

The first convex lens 235 may control light input from the homogenizer 234. In an embodiment, for example, the first convex lens 235 may control the light width of the input light to be further widened or increased.

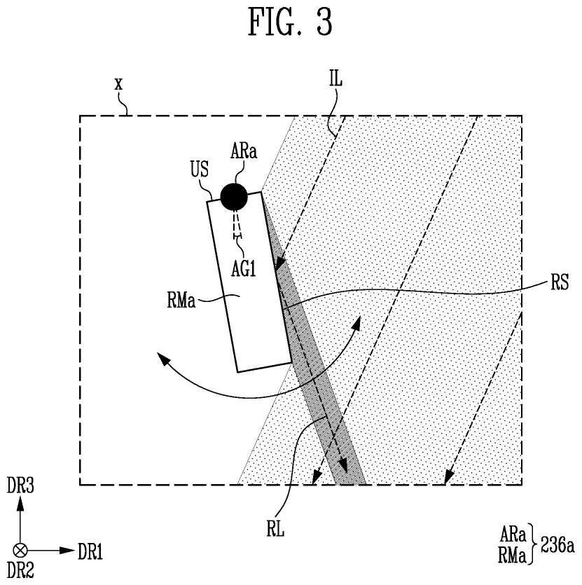

The driving mirror unit 236 may include a first driving mirror unit 236a and a second driving mirror unit 236b. The first and second driving mirror units 236a and 236b may reflect at least a portion of light input from the first convex lens 235, thereby controlling an advancing path (or light path). An operation of the driving mirror unit 236 will be described in detail with reference to FIGS. 3 to 10.

The second convex lens 237 may control the light width of light passing through the driving mirror unit 236, thereby generating output light LSRL. In an embodiment, for example, the second convex lens 237 may control the light width of the light passed through the driving mirror unit 236 to be further narrowed or decreased, thereby generating the output light LSRL.

The output light LSRL may have a line shape having a major axis length and a minor axis length.

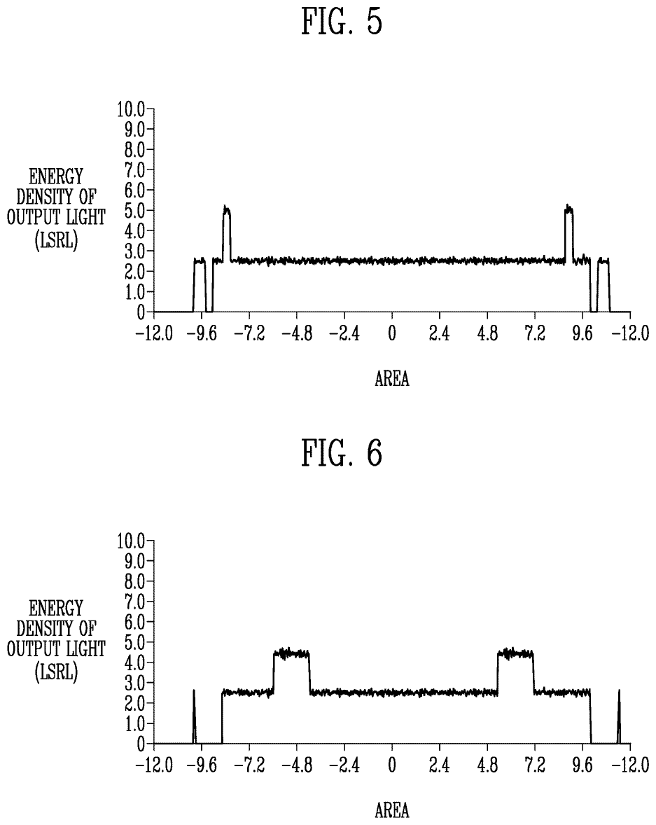

The output light LSRL may be divided into first to third output lights LSRL1, LSRL2, and LSRL3. The first and second output lights LSRL1 and LSRL2 may be generated from light obtained by combining light of which advancing path (or light path) is changed by reflection and light of which advancing path (or light path) is not changed in a process in which the light passes through the driving mirror unit 236. The third output light LSRL3 may be generated from light of which advancing path (or light path) is not changed in a process in which the light passes through the driving mirror unit 236. The first and second output lights LSRL1 and LSRL2 may have a high energy density as compared with the third output light LSRL3. This will be described later with reference to FIGS. 5 and 6.

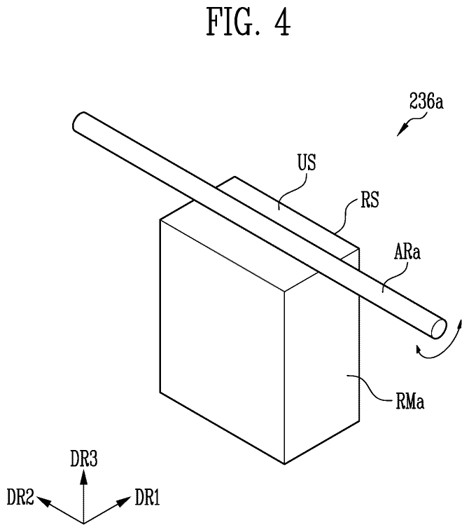

FIG. 3 is an enlarged view of the encircled portion X of FIG. 2 in accordance with a first embodiment of the disclosure. FIG. 4 is a schematic perspective view of a first driving mirror unit shown in FIG. 3. A configuration and an operation of the second driving mirror unit 236b are substantially the same as a configuration and an operation of the first driving mirror unit 236a, and therefore, the first driving mirror unit 236a will hereinafter be described in detail, and any repetitive detailed descriptions of the second driving mirror unit 236b will be omitted.

Referring to FIGS. 3 and 4, an embodiment of the first driving mirror unit 236a may include a first reflective member RMa and a first rotating shaft ARa.

The first reflective member RMa may have a three-dimensional shape (e.g., a rectangular parallelepiped shape) extending in first to third directions DR1 to DR3.

The first reflective member RMa may include a reflective surface. The reflective surface RS of the first reflective member RMa may form a first angle AG1 with an imaginary surface which is perpendicular to a ground surface and extends in the second and third directions DR2 and DR3. The magnitude of the first angle AG1 may be about zero (0) degree or greater and less than about 90 degrees.

At least a portion of light IL input to the driving mirror unit 236 may be reflected from the reflective surface RS such that an advancing path (or light path) thereof is changed (or at least a portion of the light IL input to the driving mirror unit 236 may form reflected light RL). The reflected light RL may transmit through the second convex lens 237. Light of which advancing path (or light path) is not changed in the light IL input to the driving mirror unit 236 may also transmit through the second convex lens 237.

The first rotating shaft ARa may have a three-dimensional shape (e.g., a cylindrical shape) extending in the second direction DR2. The first rotating shaft

ARa may be coupled to an upper surface US adjacent to the reflective surface RS of the first reflective member RMa.

The first rotating shaft ARa may be rotated at a certain angle clockwise or counterclockwise by an external device (not shown) (see an arrow indicated by a solid line). The direction of the reflective surface RS of the first reflective member RMa (i.e., the direction in which the reflective surface RS of the first reflective member RMa faces) may be changed by an operation of the first rotating shaft ARa (e.g., rotation at a certain angle from the imaginary surface which is perpendicular to the ground surface and extends in the second and third directions DR2 and DR3). In an embodiment, for example, the first angle AG1 may be changed based on the operation of the first rotating shaft ARa.

FIGS. 5 and 6 are graphs illustrating energy density of the output light for each area according to the magnitude of the first angle shown in FIG. 3. The horizontal axis represents position of the output light LSRL in the first direction DR1, and the vertical axis represents magnitude of energy density of the output light LSRL. FIG. 5 is a graph illustrating magnitude of energy density of the output light LSRL for each area when the magnitude of the first angle AG1 is about 5 degrees. FIG. 6 is a graph illustrating magnitude of energy density of the output light LSRL for each area when the magnitude of the first angle AG1 is about 20 degrees.

Referring to FIG. 5, an energy density of the output light LSRL may be different for each area. It can be seen that the output light LSRL has a highest energy density of about 5.248 watts per square centimeter (W/cm²) in an area close to opposing ends thereof, or the vicinity of opposing ends thereof. The reason why the energy density of the area close to opposing ends becomes high is as follows.

Each of light of which advancing path (or light path) is changed by reflection and light of which advancing path (or light path) is not changed in a process in which the light passes through the driving mirror unit 236 (see FIG. 2) may transmit through the second convex lens 237 and then constitute the output light LSRL. Any area of the output light LSRL may be formed from the light of which advancing path (or light path) is changed by reflection and the light of which advancing path (or light path) is not changed in the process in which the light passes through the driving mirror unit 236. As a result, several lights are combined in the area close to opposing ends, such that the energy density in the area close to opposing ends may become high.

On the other hand, it can be seen that the output light LSRL has an energy density of about 2.5 W/cm² in the other area. Light of which advancing path (or light path) is not changed in the process in which the light passes through the driving mirror unit 236 may pass through the second convex lens 237 and then form output light of the corresponding area.

Referring to FIG. 6, an energy density of the output light LSRL may be different for each area. It can be seen that the output light LSRL has a highest energy density of about 4.82 W/cm² in the area close to opposing ends, or the vicinity of opposing ends thereof.

However, it can be seen that, as compared with FIG. 5, an area in which the output light LSRL has a highest energy density moves toward a central portion of the output light LSRL (e.g., a point corresponding to 0 on the X axis of the graph shown in FIG. 6). In other words, it can be seen that, as the first angle AG1 becomes larger, the area in which the output light LSRL has the highest energy density moves toward the central portion.

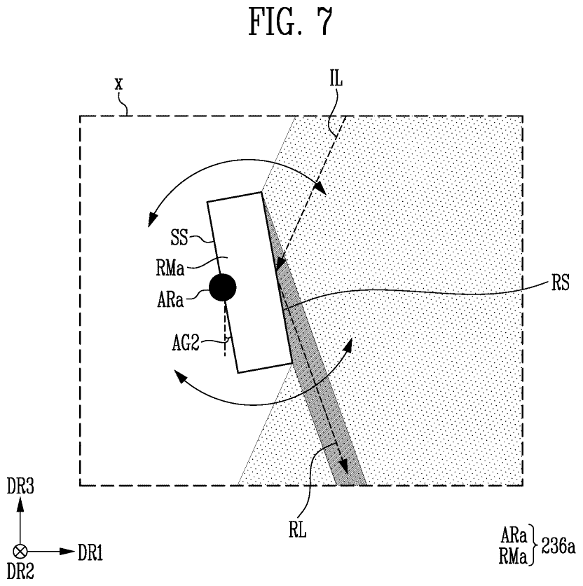

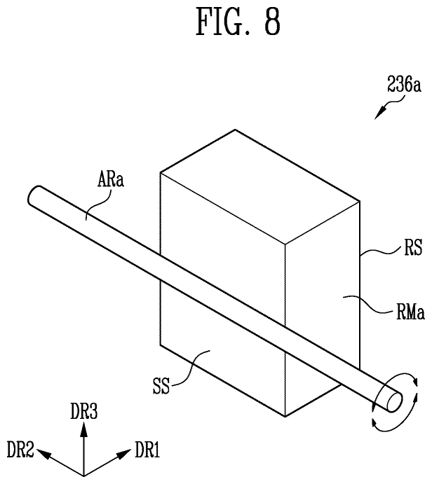

FIG. 7 is an enlarged view of the encircled portion X of FIG. 2 in accordance with another embodiment of the disclosure. FIG. 8 is a schematic perspective view of a first driving mirror unit shown in FIG. 7. A configuration and an operation of the second driving mirror unit 236b are substantially to the same as a configuration and an operation of the first driving mirror unit 236a, and therefore, the first driving mirror unit 236a will hereinafter be described in detail, and any repetitive detailed descriptions of the second driving mirror unit 236b will be omitted.

Referring to FIGS. 7 and 8, an embodiment of the first driving mirror unit 236a may include a first reflective member RMa and a first rotating shaft ARa.

The first reflective member RMa may have a three-dimensional shape (e.g., a rectangular parallelepiped shape) extending in the first to third directions DR1 to DR3.

The first reflective member RMa may include a reflective surface. The reflective surface RS of the first reflective member RMa may form a second angle AG2 with an imaginary surface which is perpendicular to a ground surface and extends in the second and third directions DR2 and DR3. The magnitude of the second angle AG2 may be about zero (0) degree or greater and less than about 90 degrees.

At least a portion of light IL input to the driving mirror unit 236 may be reflected from the reflective surface RS such that an advancing path (or light path) thereof is changed (or at least a portion of the light IL input to the driving mirror unit 236 may form reflected light RL). The reflected light RL may transmit through the second convex lens 237. Light of which advancing path (or light path) is not changed in the light IL input to the driving mirror unit 236 may also transmit through the second convex lens 237.

The first rotating shaft ARa may have a three-dimensional shape (e.g., a cylindrical shape) extending in the second direction DR2. The first rotating shaft ARa may be coupled to an opposite surface SS opposite to the reflective surface RS of the first reflective member RMa.

The first rotating shaft ARa may be rotated at a certain angle clockwise or counterclockwise by an external device (not shown) (see an arrow indicated by a solid line). The direction of the reflective surface RS of the first reflective member RMa may be changed by an operation of the first rotating shaft ARa (e.g., rotation at a certain angle from the imaginary surface which is perpendicular to the ground surface and extends in the second and third directions DR2 and DR3). In an embodiment, for example, the second angle AG2 may be changed based on the operation of the first rotating shaft ARa.

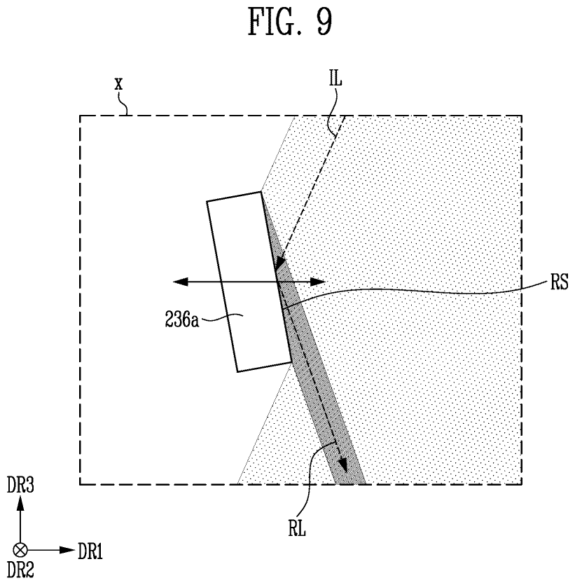

FIG. 9 is an enlarged view of the encircled portion X of FIG. 2 in accordance with another embodiment of the disclosure. A configuration and an operation of the second driving mirror unit 236b are substantially to the same as a configuration and an operation of the first driving mirror unit 236a, and therefore, the first driving mirror unit 236a will hereinafter be described in detail, and any repetitive detailed descriptions of the second driving mirror unit 236b will be omitted.

Referring to FIG. 9, an embodiment of the first driving mirror unit 236a may have a three-dimensional shape (e.g., a rectangular parallelepiped shape) extending in the first to third directions DR1 to DR3.

The first driving mirror unit 236a may include a reflective surface RS. At least a portion of light IL input to the driving mirror unit 236 may be reflected from the reflective surface RS such that an advancing path (or light path) thereof is changed (or at least a portion of the light IL input to the driving mirror unit 236 may form reflected light RL). The reflected light RL may transmit through the second convex lens 237. Light of which advancing path (or light path) is not changed in the light IL input to the driving mirror unit 236 may also transmit through the second convex lens 237.

The first driving mirror unit 236a may be moved in the first direction DR1 or the opposite direction of the first direction DR1 by an external device (not shown).

The position of the reflective surface RS of the first driving mirror unit 236a may be changed by an operation of the first driving mirror unit 236a (e.g., movement in the first direction DR1). Accordingly, a position at which reflection is made by the reflective surface RS, and the like may vary on a line extending in the first direction DR1. In addition, as an area in which the reflected light RL reaches varies, the position of an area in which the energy density is highest in the output light LSRL may vary. In an embodiment, for example, as the first driving mirror unit 236a may moves in the first direction DR1, the position of the area in which the energy density is highest in the output light LSRL may be moved to a central portion.

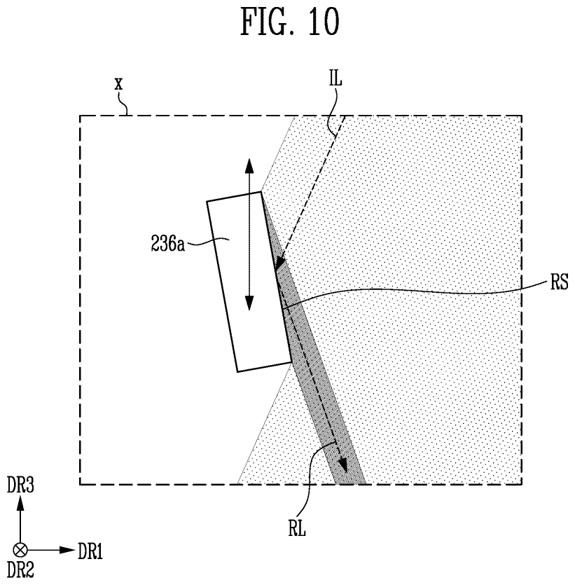

FIG. 10 is an enlarged view of the encircled portion X of FIG. 2 in accordance with another embodiment of the disclosure. A configuration and an operation of the second driving mirror unit 236b are substantially to the same as a configuration and an operation of the first driving mirror unit 236a, and therefore, the first driving mirror unit 236a will hereinafter be described in detail and any repetitive detailed descriptions of the second driving mirror unit 236b will be omitted.

Referring to FIG. 10, an embodiment of the first driving mirror unit 236a may have a three-dimensional shape (e.g., a rectangular parallelepiped shape) extending in the first to third directions DR1 to DR3.

The first driving mirror unit 236a may include a reflective surface RS. At least a portion of light IL input to the driving mirror unit 236 may be reflected from the reflective surface RS such that an advancing path (or light path) thereof is changed (or at least a portion of the light IL input to the driving mirror unit 236 may form reflected light RL). The reflected light RL may transmit through the second convex lens 237. Light of which advancing path (or light path) is not changed in the light IL input to the driving mirror unit 236 may also transmit through the second convex lens 237.

The first driving mirror unit 236a may be moved in the third direction DR3 or the opposite direction of the third direction DR3 by an external device (not shown).

The position of the reflective surface RS of the first driving mirror unit 236a may be changed by an operation of the first driving mirror unit 236a (e.g., movement in the third direction DR3). Accordingly, a position at which reflection is made by the reflective surface RS, and the like may vary on a line extending in the first direction DR1. In addition, as an area in which the reflected light RL reaches varies, the position of an area in which the energy density is highest in the output light LSRL may vary. In an embodiment, for example, as the first driving mirror unit 236a may moves in the third direction DR3, the position of the area in which the energy density is highest in the output light LSRL may be moved to a central portion.

FIG. 11 is a schematic view illustrating a stage unit in accordance with embodiments of the disclosure. FIG. 11 may be a view illustrating the stage unit 300 shown in FIG. 1. In FIG. 11, a plan view of the stage unit 300 is illustrated.

In FIG. 11, the stage unit 300 having two stages is representatively illustrated. Features described below may be properly modified, to be applied to a case where the stage unit includes a single stage.

For convenience of illustration and description, a carrier substrate and a display device, which are disposed on a first stage STG1 and a second stage STG2, are omitted in FIG. 11.

Referring to FIG. 11, an embodiment of the stage unit 300 may include first moving guides MG1, second moving guides MG2, moving units MU, the first stage STG1, and the second stage STG2.

The first moving guides MG1 may be disposed on a bottom surface of the stage unit 300. Each of the first moving guides MG1 may extend along the first direction DR1. The first moving guides MG1 may be arranged along the second direction DR2 different from the first direction DR1. The first moving guides MG1 may be spaced apart from each other in the second direction DR2.

The moving units MU may be disposed on the first moving guides MG1. The moving units MU may move along the first moving guides MG1 in the first direction DR1.

In an embodiment, as shown in FIG. 11, four moving units MU are disposed at respective corners. However, embodiments of the disclosure are not limited thereto. In some embodiments, the number or positions of moving units MU may be variously designed or modified.

Moving units MU facing each other in the second direction DR2 may be coupled to each other through the second moving guides MG2. Each of the second moving guides MG2 may extend along the second direction DR2. The second moving guides MG2 may be arranged along the first direction DR1. The second moving guides MG2 may be spaced apart from each other in the first direction DR1.

The first stage STG1 and the second stage STG2 may be disposed on the second moving guides MG2. Also, the first stage STG1 and the second stage STG2 may be disposed between the moving units MU. In an embodiment, for example, the first stage STG1 may be disposed at one side of the stage unit 300, and the second stage STG2 may be disposed at another side of the stage unit 300. The first stage STG1 and the second stage STG2 may move along the second moving guides MG2 in the second direction DR2.

An operation of the stage unit 300 will hereinafter be described in detail.

First, the moving units MU at opposing sides of the first stage STG1 may move along the first moving guides MG1 such that the first stage STG1 is located in a laser area AL. The laser area AL may be an area onto which the output light LSRL is incident.

As described above with reference to FIG. 2, in some embodiments, the output light LSRL may have a line shape having a major axis length and a minor axis length.

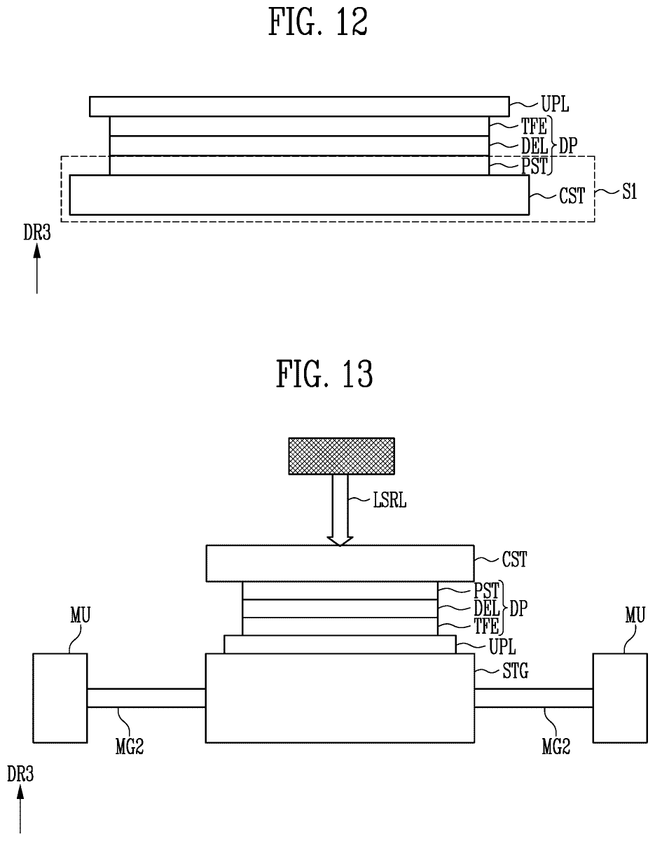

When the first stage STG1 is located in the laser area AL, the output light LSRL may be incident onto a back surface (or lower surface) of a carrier substrate CST (see FIG. 12) disposed on the first stage STG1. The back surface of the carrier substrate CST may be a surface opposite to a front surface (or upper surface) on which a light emitting element on a panel substrate PST (see FIG. 12) is disposed.

While the output light LSRL is incident, the stage STG1 may move in the second direction DR2. Accordingly, the output light LSRL may be uniformly incident onto the back surface of the carrier substrate CST (see FIG. 12) disposed on the first stage STG1. Consequently, the panel substrate PST (see FIG. 12) may be lifted off from the carrier substrate CST (see FIG. 12).

While lifting-off on the first stage STG1 is performed, another carrier substrate may be disposed on the second stage STG2.

When the lifting-off on the first stage STG1 is ended, the moving units MU at both opposing sides of the first stage STG1 may move along the first moving guides MG1 such that the first stage STG1 is located out of the laser area AL. In addition, the moving units MU at both opposing sides of the second stage STG2 may move along the first moving guides MG1 such that the second stage STG2 is located in the laser area AL.

While lifting-off on the second stage STG2 is performed, a new carrier substrate may be disposed on the first stage STG1.

The operation may be alternately and repeatedly performed on each of the first stage STG1 and the second stage STG2.

FIG. 12 is a schematic view illustrating a carrier substrate and a display panel, which may be disposed in the stage unit shown in FIG. 11.

Referring to FIG. 12, a display panel DP may include a panel substrate PST, a display element layer DEL, and an encapsulation layer TFE.

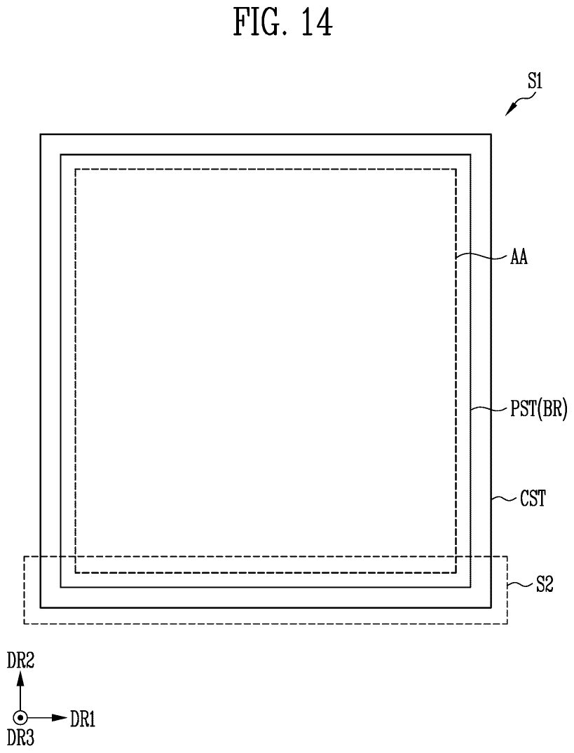

First, a carrier substrate CST may be provided on a stage STG (see FIG. 13). The carrier substrate CST may include a rigid material to serve as a support in a process of manufacturing the display device DP. The carrier substrate CST may include a transparent material to allow laser to be transmitted therethrough in a subsequent lift-off process. In an embodiment, for example, the carrier substrate CST may include or be made of glass using SiO₂ as a main component. In an embodiment, the carrier substrate CST may include or be made of at least one selected from borosilicate glass, fused silica glass, and quartz glass.

The panel substrate PST may be formed or disposed on a front surface of the carrier substrate CST. In some embodiments, the panel substrate PST may be a flexible substrate.

The panel substrate PST may include a plastic material. In an embodiment, for example, the panel substrate PST may include or be formed of polyamide or polyimide, which has high heat resistance to endure a high temperature process such as a low temperature poly-silicon (LTPS) manufacturing process and flexibility when the polyamide or polyimide is processed in a film form. The panel substrate PST may be formed by coating a polyamide or polyimide solution on the carrier substrate CST through spin coating and then curing the coated solution, or be formed by attaching or laminating a film-type polyamide or polyimide substrate to the carrier substrate CST, using an adhesive material.

The display element layer DEL may be formed or disposed on a front surface of the panel substrate PST.

Although not shown in the drawings, the display element layer DEL may include a light emitting element, a circuit element for driving the same, and the like. In some embodiments, the light emitting element may be an organic light emitting element. However, embodiments of the disclosure are not limited thereto, and the light emitting element may include various display elements such as a liquid crystal display element or an electrophoretic display element in addition to the organic light emitting element.

The encapsulation layer TFE may be formed or disposed on a front surface of the display element layer DEL. The encapsulation layer TFE may seal the display element layer DEL.

The encapsulation layer TFE may be provided in the form of a thin film or a multi-layer. In an embodiment, for example, the encapsulation layer TFE may be a thin film encapsulation layer. The encapsulation layer TFE may have a structure in which a layer including or made of an inorganic material such as silicon oxide (SiOₓ) or silicon nitride (SiNₓ) and a layer including or made of an organic material such as epoxy or polyimide are alternately formed. However, embodiments of the disclosure are not limited thereto, and the encapsulation layer TFE may include a layer including or made of low melting glass.

An upper protective layer UPL may be formed or disposed on a front surface of the encapsulation layer TFE.

When a process of manufacturing the display panel DP is completed, the panel substrate PST of the display device DP may be lifted off from the carrier substrate CST.

The upper protective layer UPL may effectively prevent the encapsulation layer TFE from being damaged while the panel substrate PST is removed or lifted off from the carrier substrate CST. The upper protective layer UPL may be removed after the panel substrate PST is removed or lifted off from the carrier substrate CST.

FIG. 13 is a schematic view illustrating an operation of the laser lift-off apparatus in accordance with embodiments of the disclosure. FIG. 13 illustrates an operation in which the laser lift-off apparatus 10 lifts off the panel substrate PST and the carrier substrate CST, which are shown in FIG. 12, from each other. In FIG. 13, a sectional view of the stage unit 300 in accordance with the embodiments of the disclosure is illustrated.

Referring to FIG. 13, the carrier substrate CST may be provided on a stage STG. The stage STG shown in FIG. 13 may correspond to any one of the first stage STG1 and the second stage STG2, which are shown in FIG. 11. In an embodiment, for example, the carrier substrate CST may

be disposed on the stage STG in a state in which the carrier substrate CST is turned upside down such that the front surface thereof faces downward and the back surface thereof faces upward. That is, the carrier substrate CST may be disposed on the stage STG such that the upper protective layer UPL formed on the front surface of the display device DP is in contact with the stage STG. The stage STG may provide an area in which the carrier substrate CST is disposed.

In an embodiment, output light LSRL having a predetermined energy density may be incident onto the back surface of the carrier substrate CST to allow the panel substrate PST to be lifted off from the carrier substrate CST. When the output light LSRL is incident onto the front surface of the carrier substrate CST, the display element layer DEL of the display panel DP may be broken or damaged. In an embodiment, the output light LSRL may be incident onto the back surface of the carrier substrate CST to protect the display element layer DEL therefrom.

While the output light LSRL is incident, the stage STG may move along the second moving guide MG2. Therefore, the output light LSRL may be incident along a major axis of the panel substrate PST.

A portion of the panel substrate PST, which is in contact with the carrier substrate CST, may absorb light having a predetermined energy density from the output light LSRL.

When the absorbed energy exceeds a specific level, bonding chains of polyamide or polyimide, which constitutes the panel substrate PST, may be broken. When the bonding chains are broken, the carrier substrate CST and the panel substrate PST may be lifted off from each other.

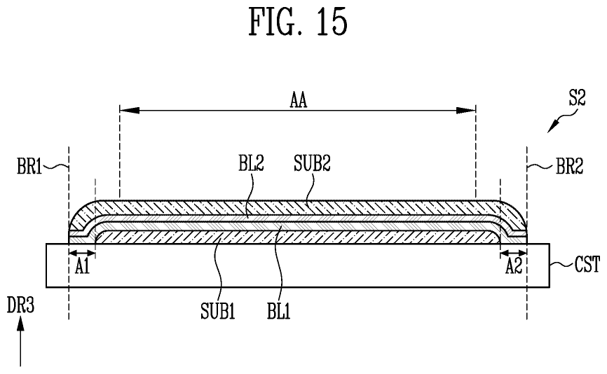

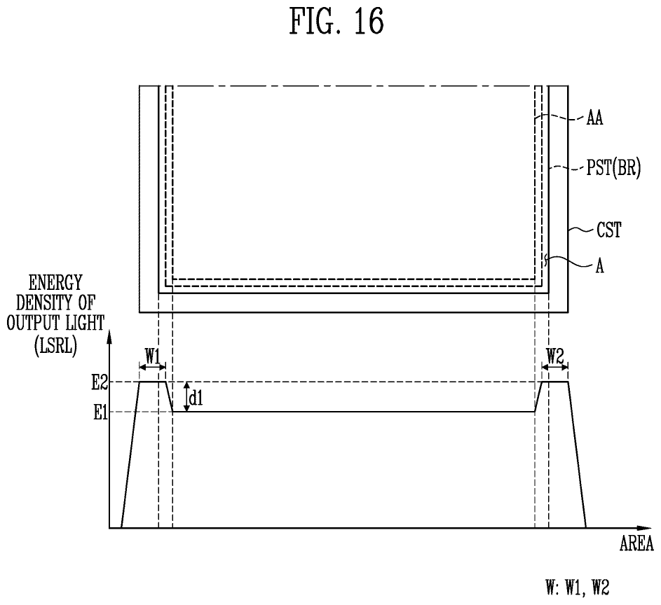

FIG. 14 is a schematic plan view of area S1 shown in FIG. 12. FIG. 15 is a schematic plan view of area S2 shown in FIG. 14. FIG. 14 schematically illustrates an arrangement of the carrier substrate CST and the panel substrate PST. FIG. 15 schematically illustrates a section of the carrier substrate CST and the panel substrate PST. Hereinafter, the process of lifting off the carrier substrate CST and the panel substrate PST from each other will be described in greater detail with reference to FIGS. 14 and 15.

In an embodiment, the panel substrate PST may include a first substrate SUB1, a first barrier layer BL1, a second barrier layer BL2, and a second substrate SUB2. The panel substrate PST may include an active area AA in which a pixel defined by the display element layer DEL (see FIG. 12) is disposed.

The carrier substrate CST may include a first boundary area BR1 and a second boundary area BR2, which correspond to a boundary area BR. The boundary area BR may be a boundary of an area in which the panel substrate PST and the carrier substrate CST overlap each and an area in which the panel substrate PST and the carrier substrate CST do not overlap each other. In an embodiment, for example, with respect to the boundary area BR, the panel substrate PST may be disposed inside the boundary area BR, and may not be disposed outside the boundary area BR.

The first substrate SUB1 may be disposed on the carrier substrate CST. The first substrate SUB1 may have an area smaller than an area of the carrier substrate CST. Therefore, the first substrate SUB1 may not overlap at least a portion of the carrier substrate CST.

The first substrate SUB1 may include an organic material. In some embodiments, may include at least one selected from polyamide resin and polyimide resin. However, embodiments of the disclosure are not limited thereto.

The first barrier layer BL1 may be disposed over the first substrate SUB1. The first barrier layer BL1 may have an area greater than the area of the first substrate SUB1. Therefore, the first barrier layer BL1 may entirely cover the first substrate SUB1. The first barrier layer BL1 may be in contact with at least a portion of the carrier substrate CST.

The first barrier layer BL1 may include an inorganic material. In some embodiments, the inorganic material may include at least one selected from silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and silicon oxynitride (SiOₓN_{y}). However, embodiments of the disclosure are not limited thereto.

The second barrier layer BL2 may be disposed over the first barrier layer BL1. The second barrier layer BL2 may have an area greater than the area of the first barrier layer BL1. Therefore, the second barrier layer BL2 may entirely cover the first barrier layer BL1.

The second barrier layer BL2 may include an inorganic material. The inorganic material may include at least one selected from the materials described above with reference to the first barrier layer BL1.

The second substrate SUB2 may be disposed over the second barrier layer BL2. The second substrate SUB2 may have an area greater than the area of the first substrate SUB1. The second substrate SUB2 and the first substrate SUB1 may have end portions not overlapping each other. When the second substrate SUB2 has the area greater than the area of the first substrate SUB1, the second substrate SUB2 may form a protrusion area A protruding further than the first substrate SUB1 in a length direction of the first substrate SUB1. The protrusion area A may include a first protrusion area A1 and a second protrusion area A2.

The second substrate SUB2 may include an organic material. The organic material may include at least one selected from the materials described above with reference to the first substrate SUB1.

The protrusion area A may overlap a portion of each of the first barrier layer BL1 and the second barrier layer BL2, which are disposed between the carrier substrate CST and the second substrate SUB2.

In such an embodiment, it is desired that the laser lift-off apparatus 10 applies appropriate energy to an area in which the panel substrate PST and the carrier substrate CST are in contact with each other to allow the carrier substrate CST to be lifted off from the panel substrate PST. For example, when the laser lift-off apparatus 10 does not apply appropriate energy, the first substrate SUB1 is not properly lifted off, and therefore, a risk or probability that a component of the display device DP will be damaged may be increased.

For example, since the pixel is disposed in the active area AA, it is desired that the active area AA is lifted off with energy relatively lower than energy of an area except the active area AA to prevent the pixel from being damaged. Experimentally, when the laser lift-off apparatus 10 applies high energy to the active area AA, a risk that the first substrate SUB1 is damaged by the output light LSRL will be increased, and a risk that adhesion between components on the first substrate SUB1 is weakened and the encapsulation layer is stripped may be increased. Therefore, it is desired that the active area AA is lifted off using output light LSRL having relatively low energy among output lights LSRL incident onto the panel substrate PST. The laser lift-off apparatus 10 in accordance with embodiments of the disclosure may apply appropriately low energy to the active area AA. Thus, the risk that the encapsulation layer TFE is stripped can be reduced.

In an embodiment, since the protrusion area A is an area in which the first barrier layer BL1 and the second barrier layer BL2 are disposed between the carrier substrate CST and the second substrate SUB2, the intensity of the output light LSRL coming up to the second substrate SUB2 may be decreased. Therefore, it is desired that the protrusion area A is lifted off with relatively high energy as compared with the active area AA. When high energy is not applied to the protrusion area A, lifting-off at a portion of the second substrate SUB2 in the protrusion area A may not be effectively performed. In a process of performing lifting-off, there exists a risk that the second substrate SUB2 is damaged while a lift-off blade passes between the carrier substrate CST and the second substrate SUB2. The laser lift-off apparatus 10 in accordance with embodiments of the disclosure may apply appropriately high energy to the protrusion area A, using the driving mirror unit 236 (see FIG. 2). Thus, the risk that the second substrate SUB2 is damaged may be substantially reduced.

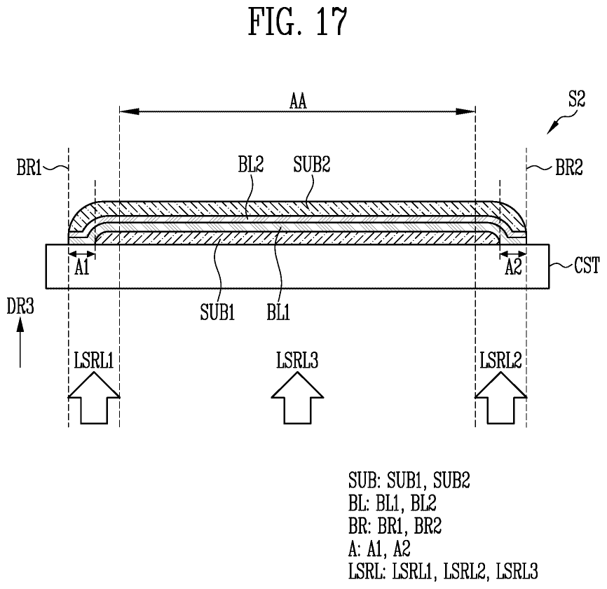

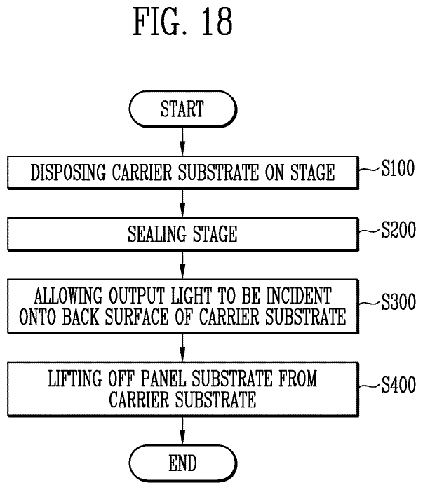

The laser lift-off apparatus 10 in accordance with embodiments of the disclosure allow appropriate energy to be provided for area as described above. Therefore, energy incident for each substrate area can be properly adjusted. This will hereinafter be described in detail with reference to FIGS. 16 and 17.

FIG. 16 is a schematic view illustrating laser energy density applied to the carrier substrate and the panel substrate when a laser lift-off process is performed in accordance with embodiments of the disclosure. FIG. 16 schematically illustrates energy density of output light LSRL applied to the carrier substrate CTS and the panel substrate PST. FIG. 17 is a schematic view illustrating that the carrier substrate and the panel substrate are lifted off from each other, using the laser lift-off apparatus in accordance with embodiments of the disclosure.

Referring to FIGS. 16 and 17, the active area AA may be lifted off by third output light LSRL3 having first energy E1. The third output light LSRL3 may have the first energy E1 which is roughly uniform in the active area AA. The protrusion area A and the boundary area BR may be lifted off by first and second output lights LSRL1 and LSRL2 having second energy E2. The first and second output lights LSRL1 and LSRL2 may have the second energy E2 which is roughly uniform in the vicinity of the protrusion area A. The first and second output lights LSRL1 and LSRL2 may respectively have first area W1 and a second area W2 as sections in which the second energy E2 is constant in an energy density graph for each area.

The first energy E1 may be lower than the second energy E2. The first energy E1 and the second energy E2 may have an energy difference d1. The energy difference d1 may be 10% to 20% of the first energy E1. The second energy E2 may be higher by 10% to 20% of the first energy E1 than the first energy E1. However, embodiments of the disclosure are not limited thereto.

Conventionally, the arrangement of a mirror and a lens of the homogenizer 234 was adjusted to vary output light LSRL to have the first energy E1 and then have the second energy E2. For example, the intensity of the output light LSRL was changed by adjusting an angle of a lens or a distance between lenses. It may be difficult to adjust the angle of the lens or the distance between the lenses such that the energy difference d1 had 10% to 20% of the first energy E1. In addition, when a position of a lens was dislocated as compared with the existing position in a process of replacing the lens, it may be difficult to vary energy by a predetermined energy difference d1.

In addition, when the angle of the lens or the distance between the lenses was adjusted, the energy may be instantaneously changed, and therefore, it may be difficult to maintain the second energy E2 for a certain time since the length of each of the first area W1 and the second area W2 was relatively short. Hence, the second energy E2 may not be supplied for a sufficient time in the boundary area BR between the panel substrate PST and the carrier substrate CST, and therefore, it may be difficult to lift off the substrates from each other.

The laser lift-off apparatus 10 in accordance with embodiments of the disclosure includes the driving mirror unit 236, thereby changing the intensity of output light LSRL passing through the driving mirror unit 236 for each area. Accordingly, in the laser lift-off apparatus 10 in accordance with embodiments of the disclosure, the degree of change of an angle of a lens or a distance between lenses can be reduced, and the length of each of the first area W1 and the second area W2 can be formed relatively long.

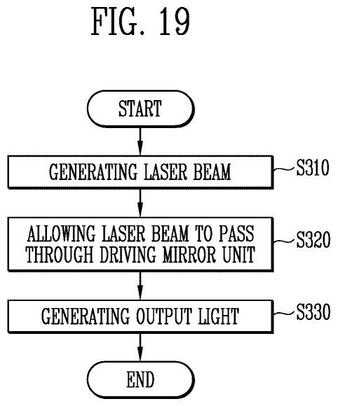

FIGS. 18 and 19 are flowcharts illustrating a laser lift-off method in accordance with embodiments of the disclosure.

Referring to FIG. 18, the laser lift-off method in accordance with embodiments of the disclosure may include a process S100 of disposing a carrier substrate on a stage, a process S200 of sealing the stage, a process S300 of allowing output light to be incident onto a back surface of the carrier substrate, and a process S400 of lifting off a panel substrate from the carrier substrate.

Referring to FIGS. 1 to 19, in the process S100 of disposing the carrier substrate on the stage, the carrier substrate CST may be disposed on the stage STG. The carrier substrate CST may be disposed on the stage STG in a state in which the carrier substrate CST is turned upside down such that the front surface thereof faces downward and the back surface thereof faces upward. That is, the carrier substrate CST may be disposed on the stage STG such that the upper protective layer UPL formed on the front surface of the display device DP is in contact with the stage STG.

The process S200 of sealing the stage may include a process of allowing the stage STG to be sealed by the chamber 400 after the carrier substrate CST is disposed on the stage STG.

The chamber 400 may seal the at least one stage from an outside to prevent an ozone gas generated due to a lift-off process from being discharged to the outside.

The process S300 of allowing the output light to be incident onto the back surface of the carrier substrate may include a process of allowing the output light LSRL to be incident onto the back surface of the carrier substrate CST after the stage STG is sealed. When the output light LSRL is incident onto the front surface of the carrier substrate CST, the display element layer DEL of the display device DP may be broken or damaged. In an embodiment, the output light LSRL may be incident onto the back surface of the carrier substrate CST such that the display element layer DEL of the display device DP may be effectively prevented from being broken or damaged.

In an embodiment, as shown in FIG. 19, the process S300 of allowing the output light to be incident onto the back surface of the carrier substrate may include a process S310 of generating a laser beam, a process S320 of allowing the laser beam to pass through a driving mirror unit, and a process S330 of generating output light.

In the process S310 of generating laser beam, the laser beam LSR may be generated through excimer laser. In some embodiments, the laser beam LSR may include a plurality of light sources.

In an embodiment, as described above with reference to FIG. 2, the laser beam LSR may transmit through the combiner 210, the telescope lens set 231, the cylindrical lens 232, the beam transfer system 233, the homogenizer 234, and the first convex lens 235.

The process S320 of allowing the laser beam to pass through the driving mirror unit may include a process of allowing lights transmitted through the first convex lens 235 to pass through the driving mirror unit 236. The advancing path (or light path) of at least some lights among the lights transmitted through the first convex lens 235 may be changed by reflection in a process in which the at least some lights pass through the driving mirror unit 236.

The process S330 of generating the output light may include a process of adjusting the light width of the light passing through the driving mirror unit 236 while the light is transmitted through the second convex lens 237. The energy density of the output light LSRL may be different for each area. In an embodiment, for example, each of the first and second output lights LSRL1 and LSRL2 formed from light obtained by combining light of which advancing path (or light path) is changed by the driving mirror unit 236 and light of which advancing path (or light path) is not changed by the driving mirror unit 236 may have a high energy density. In such an embodiment, the third output light LSRL3 formed from light of which advancing path (or light path) is not changed by the driving mirror unit 236 may have a relatively low energy density as compared with the first and second output lights LSRL1 and LSRL2.

The output light LSRL may be incident onto the back surface of the carrier substrate CST.

A portion of the panel substrate PST, which is in contact with the carrier substrate CST, may absorb light having a predetermined energy density from the output light LSRL.

When the absorbed energy exceeds a specific level, bonding chains of polyamide or polyimide, which constitutes the panel substrate PST, may be broken. When the bonding chains are broken, thermal evaporation, bursting plasma, or sonic waves may occur. Accordingly, the panel substrate PST may be lifted off from the carrier substrate CST.

In an embodiment, when the panel substrate PST and the carrier substrate CST are lifted off from each other, a lift-off blade may be used. The lift-off blade may lift off the substrates at a boundary between the panel substrate PST and the carrier substrate CST.

In accordance with embodiments of the disclosure, a laser lift-off apparatus and a laser lift-off method may effectively prevent a risk that components of a display device is damaged during a laser lift-off process.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A laser lift-off apparatus comprising:
a laser beam generating unit which generates a laser beam;
an optical unit which receives the laser beam and generates output light based on the laser beam; and
a stage unit including a stage,
wherein the optical unit includes a driving mirror unit which changes an advancing path of at least a portion of the laser beam, wherein a direction or a position of the driving mirror unit is changeable.

2. The laser lift-off apparatus of claim 1, wherein the optical unit further includes:
a combiner which combines the laser beam and provides a combined laser beam to a light former; and
the light former including the driving mirror unit, wherein the light former generates the output light based the combined laser beam.

3. The laser lift-off apparatus of claim 1, wherein the driving mirror unit includes a first driving mirror unit and a second driving mirror unit, which are spaced apart from each other in a first direction,
wherein each of the first driving mirror unit and the second driving mirror unit includes a reflective surface by which the laser beam is reflected, and
wherein a direction of the reflective surface or a position of the reflective surface is changeable.

4. The laser lift-off apparatus of claim 3, wherein the first driving mirror unit includes:
a first reflective member including the reflective surface; and
a first rotating shaft coupled to a surface adjacent to the reflective surface of the first reflective member, wherein the first rotating shaft extends in a second direction intersecting the first direction, and
wherein a direction of the reflective surface of the first driving mirror unit is changeable.

5. The laser lift-off apparatus of claim 4, wherein the reflective surface of the first driving mirror unit forms a first angle with an imaginary surface perpendicular to a ground surface, and
wherein the first angle is about 0 degree or greater and less than about 90 degrees.

6. The laser lift-off apparatus of claim 5, wherein, as a magnitude of the first angle increases, a partial area in which an energy density of the output light is the highest moves in the first direction.

7. The laser lift-off apparatus of claim 3, wherein the first driving mirror unit includes:
a first reflective member including the reflective surface; and
a first rotating shaft coupled to an opposite surface opposite to the reflective surface of the first reflective member, wherein the first rotating shaft extends in a second direction intersecting the first direction, and
wherein a direction of the reflective surface of the first driving mirror unit is changeable.

8. The laser lift-off apparatus of claim 3, wherein a position of the reflective surface of the first driving mirror unit is changeable through a movement of the first driving mirror unit in the first direction or an opposite direction of the first direction.

9. The laser lift-off apparatus of claim 3, wherein a position of the reflective surface of the first driving mirror unit is changeable through a movement of the first driving mirror unit in a third direction intersecting the first direction or an opposite direction of the third direction.

10. The laser lift-off apparatus of claim 1, wherein the laser beam has a wavelength in a range of about 300 nm to about 410 nm.

11. A laser lift-off method comprising:
disposing a carrier substrate on a stage;
sealing the stage;
allowing output light generated based on a laser beam to be incident onto a back surface of the carrier substrate; and
allowing a panel substrate disposed on a front surface of the carrier substrate to be lifted off from the carrier substrate,
wherein the allowing the output light to be incident onto the back surface of the carrier substrate includes:
generating the laser beam;
allowing at least a portion of the laser beam to pass through a driving mirror unit such that an advancing path of the at least a portion of the laser beam is changed; and
generating the output light.

12. The laser lift-off method of claim 11, wherein the allowing the output light to be incident onto the back surface of the carrier substrate further includes combining the laser beam.

13. The laser lift-off method of claim 11, wherein the driving mirror unit includes a first driving mirror unit and a second driving mirror unit, which are spaced apart from each other in a first direction,
wherein each of the first driving mirror unit and the second driving mirror unit includes a reflective surface by which the laser beam is reflected, and
wherein a direction of the reflective surface or a position of the reflective surface is changeable.

14. The laser lift-off method of claim 13, wherein the first driving mirror unit includes:
a first reflective member including the reflective surface; and
a first rotating shaft coupled to a surface adjacent to the reflective surface of the first reflective member, wherein the first rotating shaft extends in a second direction intersecting the first direction, and
wherein a direction of the reflective surface of the first driving mirror unit is changeable.

15. The laser lift-off method of claim 14, wherein the reflective surface of the first driving mirror unit forms a first angle with an imaginary surface perpendicular to a ground surface, and
wherein the first angle is about 0 degree or greater and less than about 90 degrees.

16. The laser lift-off method of claim 15, wherein an energy density of a partial area of the output light is the highest, and
wherein, as a magnitude of the first angle increases, the partial area of the output light moves in the first direction.

17. The laser lift-off method of claim 13, wherein the first driving mirror unit includes:
a first reflective member including the reflective surface; and
a first rotating shaft coupled to an opposite surface opposite to the reflective surface of the first reflective member, wherein the first rotating shaft extends in a second direction intersecting the first direction, and
wherein a direction of the reflective surface of the first driving mirror unit is changeable.

18. The laser lift-off method of claim 13, wherein a position of the reflective surface of the first driving mirror unit is changeable through a movement of the first driving mirror unit in the first direction or an opposite direction of the first direction.

19. The laser lift-off method of claim 13, wherein a position of the reflective surface of the first driving mirror unit is changeable through a movement of the first driving mirror unit in a third direction intersecting the first direction or an opposite direction of the third direction.

20. The laser lift-off method of claim 11, wherein the laser beam has a wavelength in a range of about 300 nm to about 410 nm.
